(19) United States
(12) Patent Application Publication
(10) Pub. No.: US 2026/0076076 A1
(43) Pub. Date: Mar. 12, 2026

(54) DISPLAY DEVICE AND ELECTRONIC DEVICE INCLUDING THE SAME

(71) Applicant: Samsung Display Co., LTD., Yongin-si (KR)

(72) Inventors: Jun Hyuk WOO, Yongin-si (KR); Rae Young KIM, Yongin-si (KR); Ree Hyang KIM, Yongin-si (KR); Soo Dong KIM, Yongin-si (KR); Jong Min OK, Yongin-si (KR); Je Won YOO, Yongin-si (KR); Jong Beom HONG, Yongin-si (KR)

(21) Appl. No.: 19/171,509

(22) Filed: Apr. 7, 2025

(30) Foreign Application Priority Data
Sep. 10, 2024 (KR) 10-2024-0122806

(51) Int. Cl. H10K 59/80; G06F 3/041; G06F 3/044; H10K 59/40

(52) U.S. Cl. CPC H10K 59/879; G06F 3/0412; H10K 59/40; H10K 59/873; G06F 3/04164; G06F 3/0446

(57) ABSTRACT

A display device includes a substrate; a plurality of light-emitting elements disposed on the substrate, the light-emitting elements being arranged in a plurality of light emitting areas, which output light, respectively; an encapsulation layer disposed on the plurality of light-emitting elements; a first organic pattern disposed on the encapsulation layer and located between adjacent ones of the light emitting areas; a second organic pattern and a third organic pattern, which are disposed on the first organic pattern, spaced apart from each other, and between the adjacent ones of the light emitting areas; and a fourth organic pattern disposed on the first organic pattern, the second organic pattern and the third organic pattern, where a refractive index of the first organic pattern, a refractive index of the second organic pattern and a refractive index of the third organic pattern are each smaller than a refractive index of the fourth organic pattern.

This application claims priority to Korean Patent Application No. 10-2024-0122806, filed on Sep. 10, 2024, and all the benefits accruing therefrom under 35 U.S.C. § 119, the content of which in its entirety is herein incorporated by reference.

### BACKGROUND

### 1. Field of the Disclosure

The present disclosure relates to a display device and an electronic device including thereof.

### 2. Description of the Related Art

As communication technology and media evolve, display devices are used to display images in a variety of places and environments. In particular, a variety of types of display devices such as liquid-crystal display (LCD) devices and organic light-emitting display (OLED) devices are widely used.

Since display devices are usually viewed from the front, a lot of research has been put into developing ways to increase the luminance in the front direction. For example, various structures are being devised to direct light traveling in the side directions of a display device toward the front direction of the display device.

### SUMMARY

Aspects of the present disclosure provide a display device that increases the amount of light exiting in the front direction of the display device.

According to some embodiments of the present disclosure, there is provided a display device including a substrate, a plurality of light-emitting elements disposed on the substrate, the light-emitting elements being arranged in a plurality of light emitting areas that output light, respectively, an encapsulation layer disposed on the plurality of light-emitting elements, a first organic pattern disposed on the encapsulation layer and located between adjacent ones of the light emitting areas, a second organic pattern and a third organic pattern, which are disposed on the first organic pattern, spaced apart from each other, and between the adjacent ones of the light emitting areas, and a fourth organic pattern disposed on the first organic pattern, the second organic pattern and the third organic pattern. A refractive index of the first organic pattern, a refractive index of the second organic pattern and a refractive index of the third organic pattern are each smaller than a refractive index of the fourth organic pattern.

The refractive index of the first organic pattern, the refractive index of the second organic pattern and the refractive index of the third organic pattern may be equal to one another.

The first organic pattern, the second organic pattern and the third organic pattern may include a same material.

The first organic pattern, the second organic pattern and the third organic pattern may be formed integrally.

An upper surface of the first organic pattern may be exposed between the second organic pattern and the third organic pattern.

An angle formed by a side surface of the first organic pattern and a lower surface of the first organic pattern may be smaller than an angle formed by a side surface of the second organic pattern and a lower surface of the second organic pattern.

The angle formed by the side surface of the first organic pattern and the lower surface of the first organic pattern may be smaller than a first angle. The first angle may be a critical angle at which total reflection of light occurs between the first organic pattern and the fourth organic pattern.

The angle formed by the side surface of the second organic pattern and the lower surface of the second organic pattern may be greater than the first angle.

An angle formed by a side surface of the third organic pattern and a lower surface of the third organic pattern may be equal to the angle formed by the side surface of the second organic pattern and the lower surface of the second organic pattern.

A minimum distance between one of the light emitting areas and the first organic pattern may be shorter than a minimum distance between the one of the light emitting areas and the second organic pattern in a direction perpendicular to a thickness direction of the substrate.

According to some embodiments of the present disclosure, there is provided a display device including a substrate, a plurality of light-emitting elements disposed on the substrate, the light-emitting elements being arranged in a plurality of light emitting areas, which output light, respectively, an encapsulation layer disposed on the plurality of light-emitting elements, a first organic pattern disposed on the encapsulation layer and located between adjacent ones of the light emitting areas, a second organic pattern and a third organic pattern, which are disposed on the first organic pattern, spaced apart from each other, and between the adjacent ones of the light emitting areas, and a touch electrode disposed on the first organic pattern. The third organic pattern covers the touch electrode.

The display device may further include a first inorganic insulating film disposed between the encapsulation layer and the first organic pattern, and a connecting electrode disposed on the first inorganic insulating film.

The touch electrode may be connected to the connecting electrode through a touch contact hole penetrating the first organic pattern.

The display device may further include a second inorganic insulating film disposed on the connecting electrode and the first inorganic insulating film.

The touch electrode may be connected to the connecting electrode through a touch contact hole penetrating the first organic pattern and the second inorganic insulating film.

The first organic pattern, the second organic pattern and the third organic pattern may be formed integrally.

The display device may further include a fourth organic pattern disposed on the first organic pattern, the second organic pattern and the third organic pattern. A refractive index of the first organic pattern, a refractive index of the second organic pattern, and a refractive index of the third organic pattern may each be lower than a refractive index of the fourth organic pattern.

An angle formed by a side surface of the first organic pattern and a lower surface of the first organic pattern may be smaller than an angle formed by a side surface of the second organic pattern and a lower surface of the second organic pattern.

The angle formed by the side surface of the first organic pattern and the lower surface of the first organic pattern may be smaller than a first angle. The first angle may be a critical angle at which total reflection of light occurs between the first organic pattern and the fourth organic pattern.

The angle formed by the side surface of the second organic pattern and the lower surface of the second organic pattern may be greater than the first angle.

According to some embodiments of the present disclosure, there is provided an electronic device including a display device, the display device including a substrate, a plurality of light-emitting elements disposed on the substrate, the light-emitting elements being arranged in a plurality of light emitting areas that output light, respectively, an encapsulation layer disposed on the plurality of light-emitting elements, a first organic pattern disposed on the encapsulation layer and located between adjacent ones of the light emitting areas, a second organic pattern and a third organic pattern disposed on the first organic pattern and spaced apart from each other between the adjacent ones of the light emitting areas, and a fourth organic pattern disposed on the first organic pattern, the second organic pattern and the third organic pattern. A refractive index of the first organic pattern, a refractive index of the second organic pattern and a refractive index of the third organic pattern are each smaller than a refractive index of the fourth organic pattern.

These and other aspects, embodiments and advantages of the present disclosure will become immediately apparent to those of ordinary skill in the art upon review of the Detailed Description and Claims to follow.

According to some embodiments of the present disclosure, it is possible to direct light that travels to a side of a display device or cannot exit to the outside of the display device toward the front side of the display device by way of refracting or totally reflecting it utilizing a difference in refractive indexes of first to fourth organic patterns. By doing so, the luminance on the front side of the display device can be increased.

According to some embodiments of the present disclosure, by forming a second organic pattern and a third organic pattern that cause total reflection in a display device, the area where total reflection occurs can be increased, thereby increasing the amount of light that is totally reflected. By doing so, the luminance on the front side of the display device can be effectively increased.

According to some embodiments of the present disclosure, by disposing a touch electrode on a first organic pattern, the distance between the touch electrode and a common electrode can be increased. By doing so, the parasitic capacitance that is generated between the touch electrode and the common electrode can be reduced, thereby effectively improving the touch sensitivity.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a display device according to some exemplary embodiments of the present disclosure;

FIG. 2 is a side view of the display device of FIG. 1;

FIG. 3 is an enlarged view showing a layout of area A of FIG. 1;

FIG. 4 is a cross-sectional view of the display panel, taken along line I-I′ of FIG. 3;

FIG. 5 is an enlarged cross-sectional view of area B shown in FIG. 4;

FIG. 6 is an enlarged, cross-sectional view of area C of FIG. 5;

FIG. 7 is a perspective view of a display device according to some embodiments of the present disclosure;

FIG. 8 is a side view of the display device of FIG. 7;

FIG. 9 is a layout diagram showing an example of the touch sensing layer of FIG. 8;

FIG. 10 is an enlarged view of area D shown in FIG. 9;

FIG. 11 is a cross-sectional view of the display panel, taken along line J-J′ of FIG. 10;

FIG. 12 is an enlarged view of area E shown in FIG. 11;

FIG. 13 is an enlarged view of area F shown in FIG. 12;

FIG. 14 is a cross-sectional view of the display panel, taken along line J-J′ of FIG. 10 according to another embodiment;

FIG. 15 is an enlarged view of area G shown in FIG. 14;

FIG. 16 is an enlarged view of area H shown in FIG. 15.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top (i.e., in the third direction (z-axis direction)), and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132 (a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

Hereinafter, exemplary embodiments of the present disclosure will be described in detail with reference to the accompanying drawings.

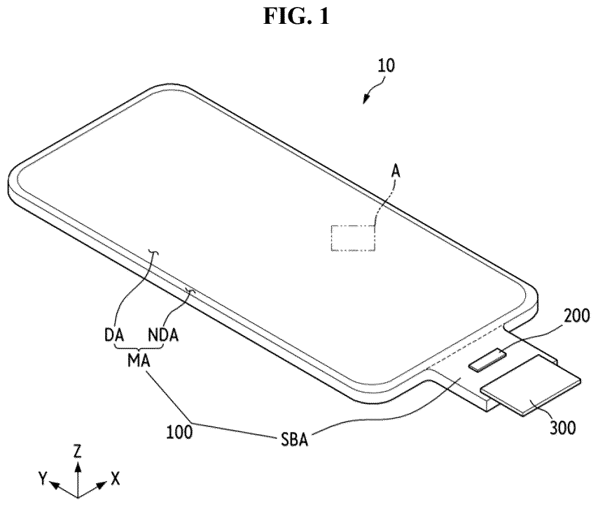

FIG. 1 is a perspective view of a display device according to some exemplary embodiments of the present disclosure.

Referring to FIG. 1, a display device 10 is for displaying still images or moving images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things (IoT). The display device 10 may be one of an organic light-emitting display device, a liquid-crystal display device, a plasma display device, a quantum dot light-emitting display device, and a micro LED display device. In the following description, an organic light-emitting display device is described as an example of the display device 10. It is, however, to be understood that the present disclosure is not limited thereto.

The display device 10 includes a display panel 100, a display driving circuit 200 and a circuit board 300.

The display panel 100 may include a main area MA and a subsidiary area SBA from one side of the main area MA.

The main area MA may be formed in a rectangular plane having shorter sides in a first direction (x-axis direction) and longer sides in a second direction (y-axis direction) intersecting the first direction (x-axis direction). Each of the corners where the short side in the first direction (x-axis direction) meets the longer side in the second direction (y-axis direction) may be rounded with a predetermined curvature or may be a right angle. The shape of the display device 10 when viewed from the top is not limited to a quadrangular shape, but may be formed in another polygonal shape, circular shape, or elliptical shape.

The main area MA may be, but is not limited to being, formed to be flat. The main area MA 10 may include curved portions formed at left and right ends thereof. The curved portions may have a predetermined curvature. In addition, the main area MA may be partially or entirely bendable or foldable.

The main area MA may include a display area DA where pixels are formed to display images, and a non-display area NDA around the display area DA.

In addition to the pixels, scan lines, data lines, and power lines connected to the pixels may be disposed in the display area DA. When the main area MA includes a curved portion, the display area DA may be disposed on the curved portion. In such case, images of the display panel 100 can also be seen on the curved portion.

The non-display area NDA may be defined as the area from the outer side of the display area DA to the edge of the display panel 100. In the non-display area NDA, a scan driver for applying scan signals to scan lines, and link lines connecting the data lines with the display driving circuit 200 may be disposed.

The subsidiary area SBA may protrude from one side of the main area MA. For example, the subsidiary area SBA may protrude from the main area MA in the opposite direction of the second direction (y-axis direction). The length of the subsidiary area SBA in the first direction (x-axis direction) may be smaller than the length of the main area MA in the first direction (x-axis direction).

The display driving circuit 200 and the circuit board 300 may be disposed in the subsidiary area SBA.

The display driving circuit 200 may output signals and voltages for driving the display panel 100. For example, the display driving circuit 200 may apply data voltages to the data lines. In addition, the display driving circuit 200 may apply supply voltage to the power line and may apply scan control signals to the scan driver. The display driving circuit 200 may be implemented as an integrated circuit (IC) and may be mounted on the display panel 100 by a chip on glass (COG) technique, a chip on plastic (COP) technique, or an ultrasonic bonding. It is, however, to be understood that the present disclosure is not limited thereto. For example, the display driving circuit 200 may be mounted on the circuit board 300.

The circuit board 300 may be attached on the display panel 100 using an anisotropic conductive film. Accordingly, lead lines of the circuit board 300 may be electrically connected to the display panel 100. The circuit board 300 may be a flexible printed circuit board, a printed circuit board, or a flexible film such as a chip on film.

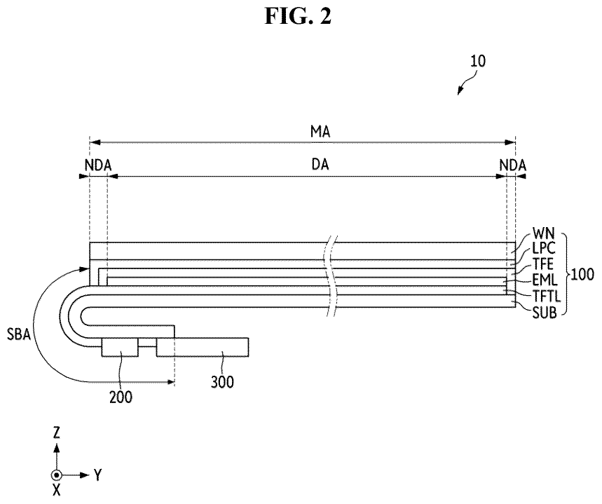

FIG. 2 is a side view of the display device of FIG. 1.

Referring to FIG. 2, the display panel 100 includes a substrate SUB, a thin-film transistor layer TFTL, a light emitting element layer EML, an encapsulation layer TFEL, and a light path controller LPC.

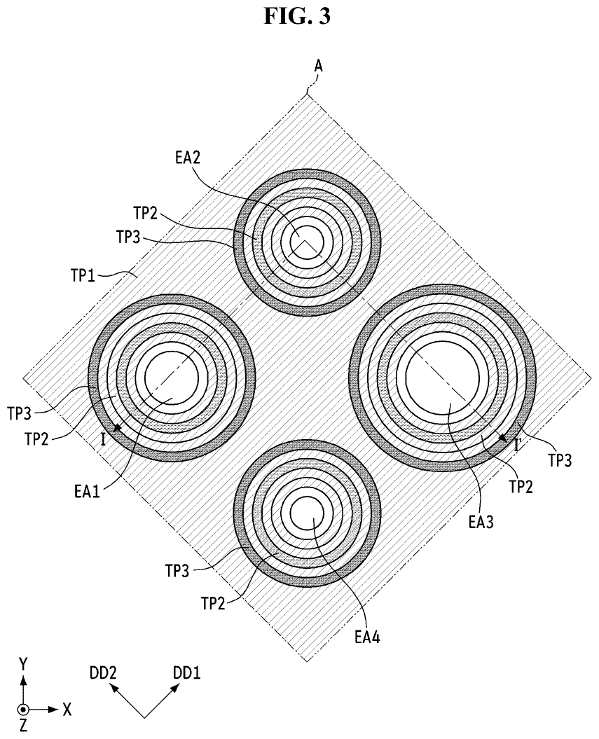

The thin-film transistor layer TFTL may be disposed on the substrate SUB. The thin-film transistor layer TFTL may be disposed in the main area MA and the subsidiary area SBA. The thin-film transistor layer TFTL includes transistors TR (see FIG. 3).

The light emitting element layer EML may be disposed on the thin-film transistor layer TFTL. The light emitting element layer EML may be disposed in the display area DA of the main area MA. The light emitting element layer EML includes light-emitting elements disposed in light emitting areas.

The encapsulation layer TFE may be disposed on the light emitting element layer EML. The encapsulation layer TFE may be disposed in the display area DA and the non-display area NDA of the main area MA. The encapsulation layer TFE includes at least one inorganic film and at least one organic film for encapsulating the light emitting element layer.

The light path controller LPC may be disposed on the encapsulation layer TFE. The light path controller LPC may be disposed in the display area DA and the non-display area NDA of the main area MA. The light path controller LPC will be described later with reference to FIG. 3.

The window member WN may be disposed on the light path controller LPC. The window member WN may be disposed in the display area DA and the non-display area NDA of the main area MA. The window member WN can protect the upper portion of the display panel 100.

The subsidiary area SBA may be bent as shown in FIG. 2, and may be located on the lower surface of the display panel 100 when it is bent. When the subsidiary area SBA is bent, it may overlap the main area MA in the thickness direction (z-axis direction) of the substrate SUB. The display driving circuit 200 may be disposed in the subsidiary area SBA.

FIG. 3 is an enlarged view showing a layout of area A of FIG. 1.

Referring to FIG. 3, a pixel may include a first light emitting area EA1 that emits light of a first color, a second light emitting area EA2 that emits light of a second color, a third light emitting area EA3 that emits light of a third color, and a fourth light emitting area EA4 that emits light of the second color. For example, the first color may be red, the second color may be green, and the third color may be blue.

The first light emitting area EA1 and the third light emitting area EA3 may be adjacent to each other in the first direction (x-axis direction). The second light emitting area EA2 and the fourth light emitting area EA4 may be adjacent to each other in the second direction (y-axis direction). The first light emitting area EA1 and the second light emitting area EA2 may be adjacent to each other in a fourth direction DD1, and the third light emitting area EA3 and the fourth light emitting area EA4 may be adjacent to each other in the fourth direction DD1. The first light emitting area EA1 and the fourth light emitting area EA4 may be adjacent to each other in a fifth direction DD2, and the second light emitting area EA2 and the third light emitting area EA3 may be adjacent to each other in the fifth direction DD2.

Each of the first to fourth light emitting areas EA1 to EA4 may have, but is not limited to, a circular shape when viewed from the top. Each of the first to fourth light emitting areas EA1 to EA4 may have a shape when viewed from the top such as a polygon including a rectangle, a diamond, and an ellipse.

For example, the size of the first light emitting area EA1 may be larger than the size of the second light emitting area EA2. The size of the second light emitting area EA2 may be equal to the size of the fourth light emitting area EA4. The size of the third light emitting area EA3 may be greater than the size of the first light emitting area EA1. It is to be understood that the embodiments of the present disclosure are not limited to the relative sizes of the first to fourth light emitting areas EA1 to EA4.

Each of the first to fourth light emitting areas EA1 to EA4 may be surrounded by the light path controller LPC. For example, each of the first to fourth light emitting areas EA1 to EA4 may be surrounded by second and third organic patterns TP2 and TP3. The first light emitting area EA1 may be surrounded by second organic patterns TP2. The second organic patterns TP2 may be surrounded by third organic patterns TP3. The second to fourth light emitting areas EA2 to EA4 may also be formed in the same shape. The widths of the first organic pattern TP1, the second organic patterns TP2 and the third organic patterns TP3 surrounding the first to fourth light-emitting units EA1 to EA4 may be all equal to one another. It should be understood, however, that the embodiments of the present disclosure are not limited thereto. The widths of the second organic patterns TP2 and the third organic patterns TP3 may have different widths depending on the first to fourth light emitting areas EA1 to EA4.

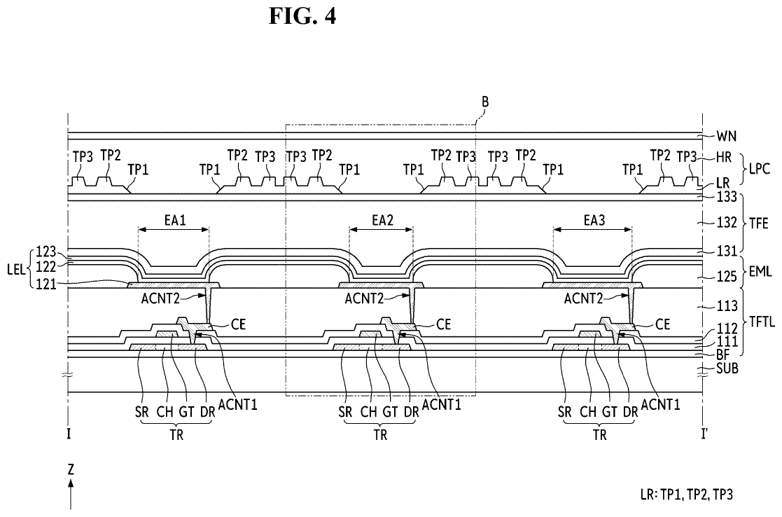

The first organic pattern TP1 may be spaced apart from the first to fourth light emitting areas EA1 to EA4 in the first direction (x-axis direction). The first organic pattern TP1 may be spaced apart from the first to fourth light emitting areas EA1 to EA4 in the second direction (y-axis direction). The first organic pattern TP1 may be disposed between the first to fourth light emitting areas EA1 to EA4 similarly to a pixel-defining layer 125 (see FIG. 4).

The second organic patterns TP2 may be spaced apart from the first to fourth light emitting areas EA1 to EA4. The second organic patterns TP2 may overlap with the first organic pattern TP1 in the first direction (x-axis direction). The second organic patterns TP2 may overlap with the first organic pattern TP1 in the second direction (y-axis direction). The second organic patterns TP2 may have a donut-like shape when viewed from the top.

The third organic patterns TP3 may be spaced apart from the first to fourth light emitting areas EA1 to EA4. The third organic patterns TP3 may be spaced apart from the second organic patterns TP2 in the first direction (x-axis direction). The third organic patterns TP3 may be spaced apart from the second organic patterns TP2 in the second direction (y-axis direction). The third organic patterns TP3 may overlap with the first organic pattern TP1 in the first direction (x-axis direction). The third organic patterns TP3 may overlap with the first organic pattern TP1 in the second direction (y-axis direction). The third organic patterns TP3 may have a donut-like shape when viewed from the top.

When the first to fourth light emitting areas EA1 to EA4 have a circular shape and the second and third organic patterns TP2 and TP3 have a donut-like shape when viewed from the top, the first to fourth light emitting areas EA1 to EA4 and the second and third organic patterns TP2 and TP3 may have substantially the same structure in the first direction (x-axis direction) and a direction intersecting the first direction (x-axis direction) when viewed from the top. In the following description, the first direction (x-axis direction) will be described for convenience of illustration.

FIG. 4 is a cross-sectional view of the display panel, taken along line I-I′ of FIG. 3.

Referring to FIG. 4, the display panel 100 may include the substrate SUB, the thin-film transistor layer TFTL disposed on the substrate SUB, the light emitting element layer EML, the encapsulation layer TFE, the light path controller LPC, and the window member WN.

The substrate SUB may be made of an insulating material such as glass, quartz and a polymer resin. Alternatively, the substrate SUB may include a metallic material. The substrate SUB may be a rigid substrate or a flexible substrate that can be bent, folded, rolled, and so on. When the substrate SUB is a flexible substrate, it may be formed of, but is not limited to, polyimide (PI).

The thin-film transistor layer TFTL may be disposed on the substrate SUB. The thin-film transistor layer TFTL may include thin-film transistors TR for each pixel, connecting electrodes CE, and a plurality of insulating films.

A buffer film BF may be disposed on the substrate SUB. The buffer film BF may be made up of multiple inorganic films stacked on one another alternately. For example, the buffer layer BF may be made up of multiple layers in which one or more inorganic layers of a silicon nitride layer, a silicon oxynitride layer, a silicon oxide layer, a titanium oxide layer and an aluminum oxide layer are alternately stacked on one another.

The active layer of each of the thin-film transistors TR may be disposed on the buffer film BF. The active layer includes a channel CH, a source electrode SR and a drain electrode DR.

The gate insulator 111 may be disposed on the active layer. The gate insulator 111 may be formed as an inorganic insulating film, for example, a silicon nitride film (SiNx), a silicon oxide film (SiOx), a silicon nitride oxide film (SiON), a titanium oxide film (TiOx), or an aluminum oxide film (AlOx).

The gate electrode GT of the transistor TR may be disposed on the gate insulator 111. The gate electrode GT may overlap with the channel CH in the third direction (z-axis direction). The gate electrode GT may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

An interlayer insulating film 112 may be disposed on the gate electrode GT of the transistor TR. The interlayer insulating film 112 may be formed of an inorganic layer, for example, a silicon nitride layer, a silicon oxynitride layer, a silicon oxide layer, a titanium oxide layer, or an aluminum oxide layer. The interlayer insulating film 112 may include a plurality of inorganic films.

A first source metal layer may be disposed on the interlayer insulating film 112. The first source metal layer includes the connecting electrodes CE. An anode connection electrode CE may be coupled to the drain electrode DR of the transistor TR through a first contact hole ACNT1 penetrating the gate insulator 111 and the interlayer insulating film 112. The anode connection electrode CE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A protective film 113 may be disposed on the first source metal layer to provide a flat surface over the transistor TR and protect the transistor TR. The protective film 113 may be implemented as an organic layer such as an acryl resin, an epoxy resin, a phenolic resin, a polyamide resin and a polyimide resin.

The light emitting element layer EML including a light-emitting element LEL and a pixel-defining layer 125 may be disposed on the protective film 113. Each of the light-emitting elements LEL includes a pixel electrode 121, a light emitting layer 122, and a common electrode 123.

Specifically, a pixel electrode layer may be disposed on the protective film 113. The pixel electrode layer includes the pixel electrode 121. The pixel electrode 121 may be connected to the anode connection electrode CE through a second contact hole ACNT2 penetrating the protective film 113. In the top-emission structure where light exits from the light emitting layer 122 toward the common electrode 123, the pixel electrode 121 may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/AI/ITO), an APC alloy and a stack structure of APC alloy and ITO (ITO/APC/ITO) in order to increase the reflectivity. The APC alloy is an alloy of silver (Ag), palladium (Pd) and copper (Cu).

The pixel-defining layer 125 may be disposed on a portion of the pixel electrode 121. The pixel-defining layer 125 may define the light emitting areas EA of the pixels. The pixel-defining layer 125 may be formed on the protective film 113 to expose a portion of the pixel electrode 121. The pixel-defining layer 125 may cover an edge of the pixel electrode 121. The pixel-defining layer 125 may be formed of an organic layer such as an acryl resin, an epoxy resin, a phenolic resin, a polyamide resin and a polyimide resin.

The light emitting layer 122 may be disposed on the pixel electrode 121. The light emitting layer 122 may be an organic light emitting layer including an organic material. Then, the light emitting layer 122 may include a hole transporting layer, an organic light-emitting layer and an electron transporting layer. When a voltage is applied to the pixel electrode and a cathode voltage is applied to the common electrode 123 through a thin-film transistor TR of the thin-film transistor layer TFTL, the holes and electrons move to the organic light emitting layer 122 through the hole transporting layer and the electron transporting layer, respectively, such that they combine in the organic light emitting layer to emit light. The pixels of the light emitting element layer EML may be disposed in the display area DA.

The common electrode 123 may be disposed on the pixel-defining layer 125 and the light emitting layer 122. The common electrode 123 may be formed to cover the light emitting layer 122. The common electrode 123 may be a common layer formed across the light emitting areas EA1, EA2, EA3 and EA4.

The thin-film encapsulation layer TFE may be disposed on the light emitting element layer EML. The thin-film encapsulation layer TFE may include a first inorganic encapsulation layer 131 and a second inorganic encapsulation layer 133 that serve to prevent oxygen or moisture from permeating into the light emitting element layer EML. The first inorganic encapsulation layer 131 and the second inorganic encapsulation layer 133 may be, but is not limited to, a silicon nitride layer, a silicon oxynitride layer, a silicon oxide layer, a titanium oxide layer, or an aluminum oxide layer.

In addition, the thin-film encapsulation layer TFEL may include a first organic encapsulation layer 132 that protects the light emitting element layer EML from particles such as dust. The first organic encapsulation layer 132 may be disposed between the first inorganic encapsulation layer 131 and the second inorganic encapsulation layer 133. The first organic encapsulation layer 132 may be, but is not limited to, an acryl resin, an epoxy resin, a phenolic resin, a polyamide resin, a polyimide resin, etc.

The thin-film encapsulation layer TFE may be disposed in the display area DA as well as the non-display area NDA. Specifically, the thin-film encapsulation layer TFE may cover the display area DA and the light emitting element layer EML and may cover the thin-film transistor layer TFTL in the non-display area NDA.

The light path controller LPC may be disposed on the thin-film encapsulation layer TFE. The light path controller LPC may include a low-refractive layer LR and a high-refractive layer HR (fourth organic pattern).

The low-refractive layer LR may include the first organic pattern TP1, the second organic patterns TP2, and the third organic patterns TP3. The low-refractive layer LR may include an organic material. The refractive index of the low-refractive layer LR may be lower than the refractive index of the high-refractive layer HR. The refractive index of the first organic pattern TP1, the refractive index of the second organic patterns TP2, and the refractive index of the third organic patterns TP3 of the low-refractive layer LR may be equal to one another. The first organic pattern TP1, the second organic patterns TP2 and the third organic patterns TP3 may include the same material. The first to third organic patterns TP1 to TP3 may be formed integrally. That is, the first to third organic patterns TP1 to TP3 may be monolithic.

The first organic pattern TP1 may be disposed on the encapsulation layer TFE. The first organic pattern TP1 may overlap with the pixel-defining layer 125 in the third direction (z-axis direction). The first organic pattern TP1 may not overlap with the first to fourth light emitting areas EA1 to EA4 in the third direction (z-axis direction).

The second organic patterns TP2 and the third organic patterns TP3 may be disposed on the first organic pattern TP1. The second organic patterns TP2 and the third organic patterns TP3 may be spaced apart from each other. Although the height of the second organic patterns TP2 is equal to the height of the third organic patterns TP3 in the drawings, the embodiments of the present disclosure are not limited thereto.

The second organic pattern TP2 adjacent to the first light emitting area EA1 may be disposed closer to the first light emitting area EA1 than the third organic pattern TP3 adjacent to the first light emitting area EA1. The second organic pattern TP2 adjacent to the second light emitting area EA2 may be disposed closer to the second light emitting area EA2 than the third organic pattern TP3 adjacent to the second light emitting area EA2. The second organic pattern TP2 adjacent to the third light emitting area EA3 may be disposed closer to the third light emitting area EA3 than the third organic pattern TP3 adjacent to the third light emitting area EA3.

The arrangement of the second organic patterns TP2 and the third organic patterns TP3 in the first light emitting area EA1 has been described as an example. The second organic patterns TP2 and the third organic patterns TP3 may be disposed in the same manner in the second to fourth light emitting areas EA2 to EA4.

The high-refractive layer HR (fourth organic pattern) may be disposed on the first organic pattern TP1, the second organic patterns TP2, the third organic patterns TP3, and the second inorganic encapsulation layer 133. The high-refractive layer HR may be in contact with the upper surface and the side surfaces of the first organic pattern TP1. The high-refractive layer HR may be in contact with the upper surface and the side surfaces of the second organic patterns TP2. The high-refractive layer HR may be in contact with the upper surface and the side surfaces of the third organic patterns TP3. The high-refractive layer HR may provide a flat surface over the low-refractive layer LR.

The refractive index of the high-refractive layer HR (fourth organic pattern) may be higher than the refractive index of the low-refractive layer LR. Accordingly, light passing through the interface between the high-refractive layer HR and the low-refractive layer LR may be refracted.

The window member WN may be disposed on the high-refractive layer HR to protect the display panel 100 from above. The window member WN may be attached on the high-refractive layer HR by a transparent adhesive member such as an optically clear adhesive (OCA) film and an optically clear resin (OCR). The window member WN may be either an inorganic material such as glass or an organic material such as plastic and polymer material.

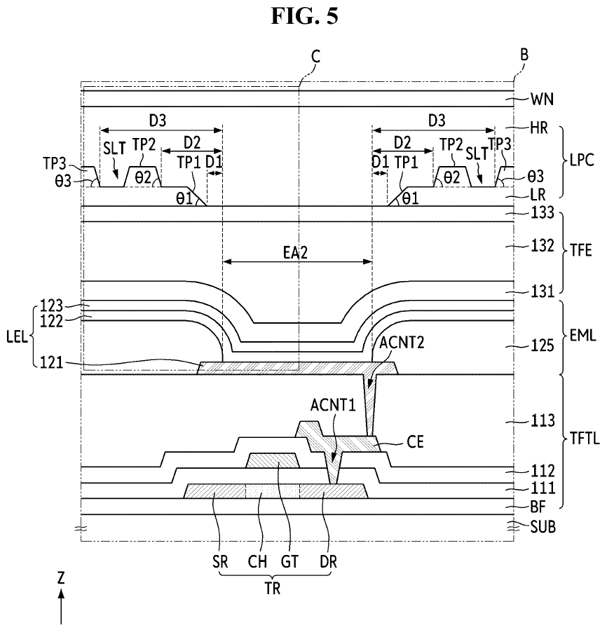

FIG. 5 is an enlarged cross-sectional view of area B shown in FIG. 4.

Referring to FIG. 5, the first organic pattern TP1 may be spaced apart from the second light emitting area EA2 in the first direction (x-axis direction). For example, the distance D1 between a side surface of the first organic pattern TP1 adjacent to the second light emitting area EA2 and the second light emitting area EA2 in the first direction (x-axis direction) may be equal to or greater than 0.1 micrometers (μm).

The angle θ1 formed by the side surface of the first organic pattern TP1 adjacent to the second light emitting area EA2 and a lower surface of the first organic pattern TP1 may be smaller than a critical angle. The “critical angle” may be an angle at which light output from the second light emitting area EA2 is totally reflected at the interface between the first organic pattern TP1 and the fourth organic pattern HR. The critical angle may be determined based on a difference between the refractive index of the low-refractive layer LR and the refractive index of the high-refractive layer HR.

TABLE 1

Low-Refractive Layer

| | |
|---|---|
| 1.50 | 1.52 |

| | |
|---|---|
| Refractive | High-Refractive Layer |

| Index | 1.60 | 1.65 | 1.70 | 1.61 |
|---|---|---|---|---|
| θ1 | 60°~69° | 60°~65° | 60°~61° | 60°~70° |
| θ2 | 70°~90° | 66°~90° | 62°~90° | 71°~90° |

| | Low-Refractive Layer | | | | |
|---|---|---|---|---|---|
| | 1.55 | | | 1.60 | |
| Refractive | High-Refractive Layer | | | | |
| Index | 1.60 | 1.65 | 1.70 | 1.65 | 1.70 |
| θ1 | 60°~75° | 60°~69° | 60°~65° | 60°~75° | 60°~69° |
| θ2 | 76°~90° | 70°~90° | 66°~90° | 76°~90° | 70°~90° |

Table 1 shows relationships among the refractive index of the low-refractive layer LR, the refractive index of the high-refractive layer HR, the angle θ1, and an angle θ2 formed by a side surface of the second organic pattern TP2 adjacent to the second light emitting area EA2 and a lower surface of the second organic pattern TP2 according to embodiments of the present disclosure. Here, when the first organic pattern TP1 and the second organic pattern TP2 are formed integrally, an imaginary surface formed by extending an upper surface of the first organic pattern TP1 can be considered as the lower surface of the second organic pattern TP2. For example, if the difference between the refractive index of the low-refractive layer LR and the refractive index of the high-refractive layer HR is equal to 0.05, the angle θ1 formed by the side surface of the first organic pattern TP1 adjacent to the second light emitting area EA2 and the lower surface of the first organic pattern TP1 may range from 60° to 75°. Referring to Table 1, there may be the 0.05 difference in refractive index if the refractive index of the low-refractive layer LR is 1.55 and the refractive index of the high-refractive layer HR is 1.60, and if the refractive index of the low-refractive layer LR is 1.60 and the refractive index of the high-refractive layer HR is 1.65.

If the difference between the refractive index of the low-refractive layer LR and the refractive index of the high-refractive layer HR is equal to 0.09, the angle θ1 formed by the side surface of the first organic pattern TP1 adjacent to the second light emitting area EA2 and the lower surface of the first organic pattern TP1 may range from 60° to 70°. Referring to Table 1, there may be the 0.09 difference in refractive index if the refractive index of the low-refractive layer LR is 1.52 and the refractive index of the high-refractive layer HR is 1.61.

If the difference between the refractive index of the low-refractive layer LR and the refractive index of the high-refractive layer HR is equal to 0.1, the angle θ1 formed by the side surface of the first organic pattern TP1 adjacent to the second light emitting area EA2 and the lower surface of the first organic pattern TP1 may range from 60° to 69°. Referring to Table 1, there may be the 0.1 difference in refractive index if the refractive index of the low-refractive layer LR is 1.50 and the refractive index of the high-refractive layer HR is 1.60, if the refractive index of the low-refractive layer LR is 1.55 and the refractive index of the high-refractive layer HR is 1.65, and if the refractive index of the low-refractive layer LR is 1.60 and the refractive index of the high-refractive layer HR is 1.70.

If the difference between the refractive index of the low-refractive layer LR and the refractive index of the high-refractive layer HR is equal to 0.15, the angle θ1 formed by the side surface of the first organic pattern TP1 adjacent to the second light emitting area EA2 and the lower surface of the first organic pattern TP1 may range from 60° to 65°. Referring to Table 1, there may be the 0.15 difference in refractive index if the refractive index of the low-refractive layer LR is 1.50 and the refractive index of the high-refractive layer HR is 1.65, and if the refractive index of the low-refractive layer LR is 1.55 and the refractive index of the high-refractive layer HR is 1.70.

If the difference between the refractive index of the low-refractive layer LR and the refractive index of the high-refractive layer HR is equal to 0.2, the angle θ1 formed by the side surface of the first organic pattern TP1 adjacent to the second light emitting area EA2 and the lower surface of the first organic pattern TP1 may range from 60° to 61°. Referring to Table 1, there may be the 0.2 difference in refractive index if the refractive index of the low-refractive layer LR is 1.50 and the refractive index of the high-refractive layer HR is 1.70.

It should be understood, however, that the embodiments of the present disclosure are not limited to the refractive index of the low-refractive layer LR and the refractive index of the high-refractive layer HR described above.

The second organic patterns TP2 may be spaced apart from the second light emitting area EA2 in the first direction (x-axis direction). The side surface of the second organic pattern TP2 adjacent to the second light emitting area EA2 in the first direction (x-axis direction) may be spaced apart from the side surface of the first organic pattern TP1 adjacent to the second light emitting area EA2. The distance D2 between the side surface of the second organic pattern TP2 adjacent to the second light emitting area EA2 and the second light emitting area EA2 may be greater than the distance D1 between the side surface of the first organic pattern TP1 adjacent to the second light emitting area EA2 and the second light emitting area EA2 in the first direction (x-axis direction).

The angle θ2 formed by the side surface of the second organic pattern TP2 adjacent to the second light emitting area EA2 and the lower surface of the second organic pattern TP2 may be greater than the angle θ1 formed by the side surface of the first organic pattern TP1 adjacent to the second light emitting area EA2 and the lower surface of the first organic pattern TP1. The angle θ2 formed by the side surface of the second organic pattern TP2 adjacent to the second light emitting area EA2 and the lower surface of the second organic pattern TP2 may be greater than the critical angle.

For example, if the difference between the refractive index of the low-refractive layer LR and the refractive index of the high-refractive layer HR is equal to 0.05, the angle θ2 formed by the side surface of the second organic pattern TP2 adjacent to the second light emitting area EA2 and the lower surface of the second organic pattern TP2 may range from 76° to 90°. Referring to Table 1, there may be the 0.05 difference in refractive index if the refractive index of the low-refractive layer LR is 1.55 and the refractive index of the high-refractive layer HR is 1.60, and if the refractive index of the low-refractive layer LR is 1.60 and the refractive index of the high-refractive layer HR is 1.65.

For example, if the difference between the refractive index of the low-refractive layer LR and the refractive index of the high-refractive layer HR is equal to 0.09, the angle θ2 formed by the side surface of the second organic pattern TP2 adjacent to the second light emitting area EA2 and the lower surface of the second organic pattern TP2 may range from 71° to 90°. Referring to Table 1, there may be the 0.09 difference in refractive index if the refractive index of the low-refractive layer LR is 1.52 and the refractive index of the high-refractive layer HR is 1.61.

For example, if the difference between the refractive index of the low-refractive layer LR and the refractive index of the high-refractive layer HR is equal to 0.1, the angle θ2 formed by the side surface of the second organic pattern TP2 adjacent to the second light emitting area EA2 and the lower surface of the second organic pattern TP2 may range from 70° to 90°. Referring to Table 1, there may be the 0.1 difference in refractive index if the refractive index of the low-refractive layer LR is 1.50 and the refractive index of the high-refractive layer HR is 1.60, if the refractive index of the low-refractive layer LR is 1.55 and the refractive index of the high-refractive layer HR is 1.65, and if the refractive index of the low-refractive layer LR is 1.60 and the refractive index of the high-refractive layer HR is 1.70.

For example, if the difference between the refractive index of the low-refractive layer LR and the refractive index of the high-refractive layer HR is equal to 0.15, the angle θ2 formed by the side surface of the second organic pattern TP2 adjacent to the second light emitting area EA2 and the lower surface of the second organic pattern TP2 may range from 66° to 90°. Referring to Table 1, there may be the 0.15 difference in refractive index if the refractive index of the low-refractive layer LR is 1.50 and the refractive index of the high-refractive layer HR is 1.65, and if the refractive index of the low-refractive layer LR is 1.55 and the refractive index of the high-refractive layer HR is 1.70.

For example, if the difference between the refractive index of the low-refractive layer LR and the refractive index of the high-refractive layer HR is equal to 0.2, the angle θ2 formed by the side surface of the second organic pattern TP2 adjacent to the second light emitting area EA2 and the lower surface of the second organic pattern TP2 may range from 62° to 90°. Referring to Table 1, there may be the 0.2 difference in refractive index if the refractive index of the low-refractive layer LR is 1.50 and the refractive index of the high-refractive layer HR is 1.70.

It should be understood, however, that the embodiments of the present disclosure are not limited to the refractive index of the low-refractive layer LR and the refractive index of the high-refractive layer HR described above.

The third organic patterns TP3 may be spaced apart from the second light emitting area EA2 in the first direction (x-axis direction). The side surfaces of the third organic patterns TP3 may be spaced apart from the side surface of the first organic pattern TP1 in the first direction (x-axis direction). The side surfaces of the third organic patterns TP3 may be spaced apart from the side surface of the second organic patterns TP2 in the first direction (x-axis direction). The distance D3 between the side surface of the third organic pattern TP3 adjacent to the second light emitting area EA2 and the second light emitting area EA2 may be greater than the distance D2 between the side surface of the second organic pattern TP2 adjacent to the second light emitting area EA2 and the second light emitting area EA2 in the first direction (x-axis direction).

The distance D3 between the side surface of the third organic pattern TP3 adjacent to the second light emitting area EA2 and the second light emitting area EA2 in the first direction (x-axis direction) may be less than a predetermined distance. The predetermined distance may refer to a distance that allows light output from the second light emitting area EA2 to reach the third organic patterns TP3. Since light outputs from the front side of the second light emitting area EA2 and the light propagates toward the third organic pattern TP3 in a diagonal direction in which the first direction (x-axis direction) and the third direction (z-axis direction) cross each other, if the third organic patterns TP3 are arranged at a distance further than the predetermined distance, the light output from the second light emitting area EA2 may not reach the third organic patterns TP3.

The angle θ3 formed by the side surface of the third organic pattern TP3 adjacent to the second light emitting area EA2 and a lower surface of the third organic pattern TP3 may be greater than the critical angle. Here, when the first organic pattern TP1 and the third organic pattern TP3 are formed integrally, an imaginary surface formed by extending an upper surface of the first organic pattern TP1 can be considered as the lower surface of the third organic pattern TP3. The angle θ3 formed by the side surface of the third organic pattern TP3 adjacent to the second light emitting area EA2 and the lower surface of the third organic pattern TP3 may be substantially equal to the angle θ2 formed by the side surface of the second organic pattern TP2 adjacent to the second light emitting area EA2 and the lower surface of the second organic pattern TP2.

Slits SLT may be formed between the second organic patterns TP2 and the third organic patterns TP3. In the slits SLT, the upper surface of the first organic pattern TP1 may be exposed. One edge of a slit SLT may correspond to one side surface of a second organic pattern TP2, and the other edge of the slit SLT may correspond to one side surface of a third organic pattern TP3. The side surface of the second organic pattern TP2 may be the opposite side surface of the other side surface of the second organic pattern TP2 adjacent to the second light emitting area EA2. The side surface of the third organic pattern TP3 may be the side surface closer to the second light emitting area EA2.

In FIG. 5, the first to third organic patterns TP1 to TP3 adjacent to the second light emitting area EA2 have been described as an example. The first to third organic patterns TP1 to TP3 adjacent to the first light emitting area EA1, the third light emitting area EA3 and the fourth light emitting area EA4 may also be formed in the same manner as described above.

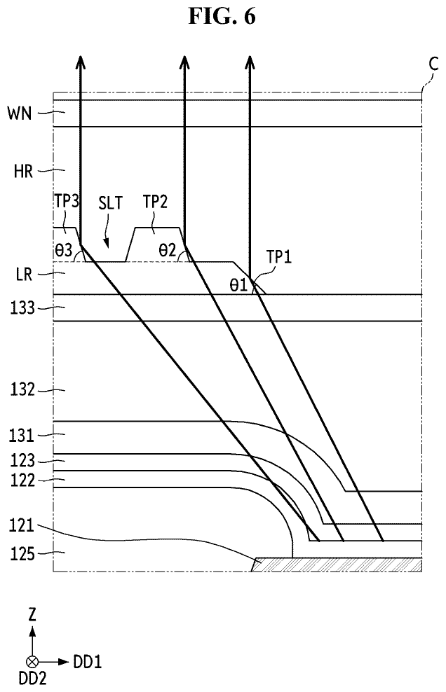

FIG. 6 is an enlarged, cross-sectional view of area C of FIG. 5.

Referring to FIG. 6, some of the lights emitted from the light emitting layer 122 may be incident on the side surface of the first organic pattern TP1. The incidence angle of the light incident on the side surface of the first organic pattern TP1 may be smaller than the critical angle. Since the refractive index of the high-refractive layer HR (fourth organic pattern) is greater than the refractive index of the first organic pattern TP1, light emitted from the light emitting layer 122 may be refracted at the side surface of the first organic pattern TP1 and may exit to the outside of the display device 10.

A portion of the light emitted from the light emitting layer 122 may be incident on the side surfaces of the second organic patterns TP2. The incidence angle of the light incident on the side surfaces of the second organic patterns TP2 may be greater than the critical angle. Since the refractive index of the high-refractive layer HR (fourth organic pattern) is greater than the refractive index of the second organic patterns TP2, light emitted from the light emitting layer 122 may be totally reflected at the side surface of the second organic pattern TP2 and may exit to the outside of the display device 10.

A portion of the light emitted from the light emitting layer 122 may be incident on the side surfaces of the third organic patterns TP3. The incidence angle of the light incident on the side surfaces of the third organic patterns TP3 may be greater than the critical angle. Since the refractive index of the high-refractive layer HR (fourth organic pattern) is greater than the refractive index of the third organic patterns TP3, light emitted from the light emitting layer 122 may be totally reflected at the side surface of the third organic patterns TP3 and may exit to the outside of the display device 10.

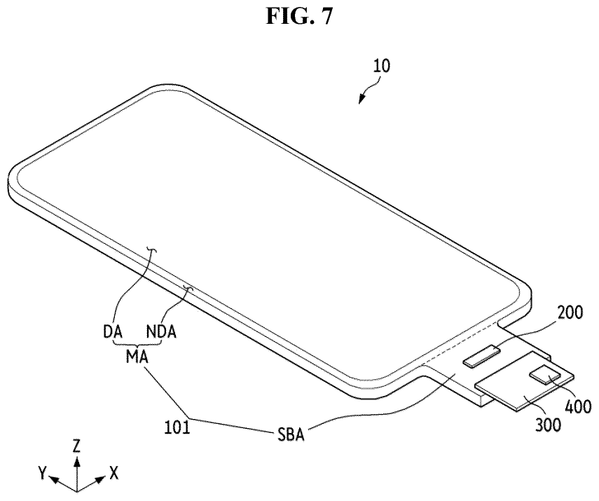

FIG. 7 is a perspective view of a display device according to some embodiments of the present disclosure. The following description will focus on differences and the redundant description will be omitted.

The display device 10 includes a display panel 101, a display driving circuit 200, a circuit board 300 and a touch driving circuit 400.

The display driving circuit 200 and the circuit board 300 may be identical to those described above with reference to FIG. 1.

The touch driving circuit 400 may be disposed on the circuit board 300. The touch driving circuit 400 may be implemented as an integrated circuit (IC) and may be attached on the circuit board 300.

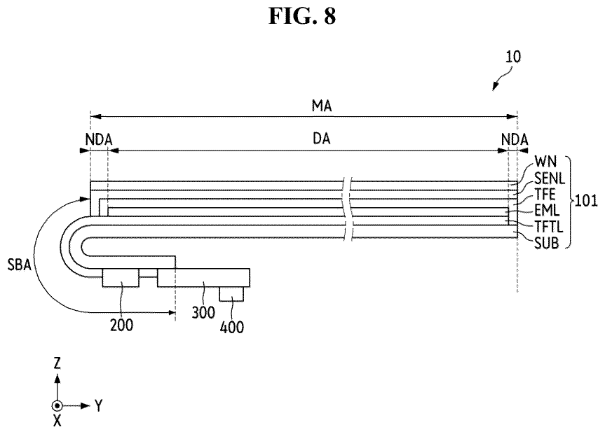

The touch driving circuit 400 may be electrically connected to the sensor electrodes of the touch sensing layer SENL (see FIG. 8) of the display panel 101. The touch driving circuit 400 applies driving signals to the sensor electrodes of the touch sensing layer SENL and measures mutual capacitances of the sensor electrodes. The driving signals may have driving pulses. The touch driving circuit 400 can determine whether a user has touched or the presence of nearby object based on the mutual capacitances. A user's touch refers to that an object such as the user's finger or a pen is brought into contact with a surface of the display device 10 disposed on the touch sensing layer SENL. The user's near proximity refers to that an object such as the user's finger and a pen is hovering over a surface of the display device 10.

FIG. 8 is a side view of the display device of FIG. 7. The following description will focus on differences and the redundant description will be omitted.

Referring to FIG. 8, the display panel 101 according to some embodiments of the present disclosure includes the substrate SUB, the thin-film transistor layer TFTL, the light emitting element layer EML, the encapsulation layer TFEL, the touch sensing layer SENL and the window member WN.

The substrate SUB, the thin-film transistor layer TFTL, the light emitting element layer EML and the encapsulation layer TFE may be formed in the same manner as the substrate SUB, the thin-film transistor layer TFTL, the light emitting element layer EML and the encapsulation layer TFE of the display panel 100 described above with reference to FIG. 2.

The touch sensing layer SENL may be disposed on the encapsulation layer TFEL. The touch sensing layer SENL may be disposed in the display area DA and the non-display area NDA of the main area MA. The touch sensing layer SENL may sense a touch of a person or an object using sensor electrodes.

The window member WN may be disposed on the touch sensing layer SENL. The window member WN may be disposed in the display area DA and the non-display area NDA of the main area MA. The window member WN can protect the upper portion of the display panel 101.

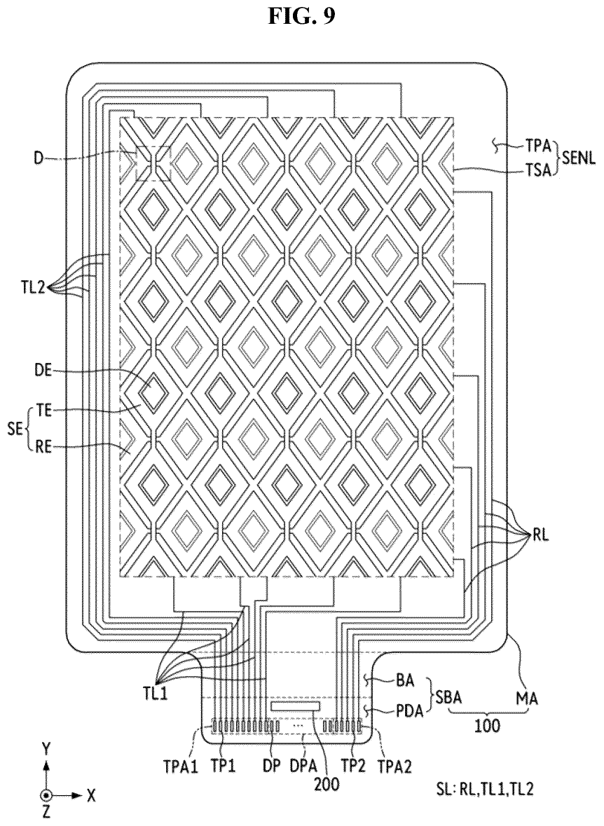

FIG. 9 is a layout diagram showing an example of the touch sensing layer of FIG. 8.

In the example shown in FIG. 9, the sensor electrodes SE of the touch sensing layer SENL include two kinds of electrodes, e.g., the driving electrodes TE and the sensing electrodes RE, by which the mutual capacitive sensing is carried out, i.e., driving signals are applied to the driving electrodes TE and then the voltages charged at the mutual capacitances can be sensed through the sensing electrodes RE. It is, however, to be understood that the present disclosure is not limited thereto.

For convenience of illustration, FIG. 9 shows only the driving electrodes TE, the sensing electrodes RE, dummy patterns DE, sensor lines TL1, TL2 and RL, and sensor pads TP1 and TP2.

Referring to FIG. 9, the touch sensing layer SENL includes a touch sensor area TSA for sensing a user's touch, and a touch peripheral area TPA disposed around the touch sensor area TSA. The touch sensor area TSA may overlap the display area DA of FIG. 7, and the touch peripheral area TPA may overlap the non-display area NDA of FIG. 7.

The touch sensor area TSA includes the driving electrodes TE, the sensing electrodes RE and the dummy patterns DE. The driving electrodes TE and the sensing electrodes RE may be electrodes for forming mutual capacitance to sense a touch of an object or a person.

The sensing electrodes RE may be arranged in the first direction (x-axis direction) and second direction (y-axis direction). The sensing electrodes RE may be electrically connected to one another in the first direction (x-axis direction). The sensing electrodes RE may be connected to one another in the first direction (x-axis direction). The sensing electrodes RE adjacent to one another in the second direction (y-axis direction) may be electrically separated from one another.

The driving electrodes TE may be arranged in the first direction (x-axis direction) and second direction (y-axis direction). The driving electrodes TE adjacent to one another in the first direction (x-axis direction) may be electrically separated from one another. The driving electrodes TE may be electrically connected to one another in the second direction (y-axis direction). For example, the driving electrodes TE adjacent to one another in the second direction (y-axis direction) may be connected through connection electrodes BE as shown in FIG. 9.

Each of the dummy patterns DE may be surrounded by the driving electrode TE or the sensing electrode RE. Each of the dummy patterns DE may be electrically separated from the driving electrode TE or the sensing electrode RE. Each of the dummy patterns DE may be spaced apart from the driving electrode TE or the sensing electrode RE. Each of the dummy patterns DE may be electrically floating.

In FIG. 9, the driving electrodes TE, the sensing electrodes RE and the dummy patterns DE each have a diamond shape when viewed from the top, but the present disclosure is not limited thereto. For example, each of the driving electrodes TE, the sensing electrodes RE and the dummy patterns DE may have other quadrangular shape than a diamond, other polygonal shapes than a quadrangular shape, a circle or an ellipse when viewed from the top.

The sensor lines TL1, TL2 and RL may be disposed in the sensor peripheral area TPA. The sensor lines TL1, TL2 and RL include sensing lines RL connected to the sensing electrodes RE, and first driving lines TL1 and second driving lines TL2 connected to the driving electrodes TE.

The sensing electrodes RE disposed on one side of the touch sensor area TSA may be connected to the sensing lines RL, respectively. For example, some of the sensing electrodes RE electrically connected in the first direction (x-axis direction) that are disposed at the right end may be connected to the sensing lines RL as shown in FIG. 9. The sensing lines RL may be connected to second sensor pads TP2, respectively. Thus, the touch driving circuit 400 may be electrically connected to the sensing electrodes RE.

The driving electrodes TE disposed on one side of the touch sensor area TSA may be connected to the first driving lines TL1, respectively, while the driving electrodes TE disposed on the other side of the touch sensor area TSA may be connected to the second driving lines TL2. For example, some of the driving electrodes TE electrically connected to one another in the second direction (y-axis direction) on the lowermost side may be connected to the first driving line TL1, while some of the driving electrodes TE disposed on the uppermost side may be connected to the second driving line TL2, as shown in FIG. 9. The second driving lines TL2 may be connected to the driving electrodes TE on the upper side of the touch sensor area TSA via the left outer side of the touch sensor area TSA.

The first driving lines TL1 and the second driving lines TL2 may be connected to the first sensor pads TP1, respectively. Thus, the touch driving circuit 400 may be electrically connected to the driving electrodes TE. The driving electrodes TE are connected to the driving lines TL1 and TL2 on both sides of the touch sensor area TSA, and receive the touch driving signals. Therefore, it is possible to prevent a difference between the touch driving signals applied to the driving electrodes TE disposed on the lower side of the touch sensor area TSA and the touch driving signals applied to the driving electrodes TE disposed on the upper side of the touch sensor area TSA which occurs due to the RC delay of the touch driving signals.

The first sensor pad area TPA1 in which the first sensor pads TP1 are disposed may be disposed on one side of the display pad area DP in which the display pads DPA are disposed. The second sensor pad area TPA2 in which the second sensor pads TP1 are disposed may be disposed on the other side of the display pad area DPA. The display pads DP may be electrically connected to data lines of the display panel 100.

The display pad area DPA, the first sensor pad area TPA1 and the second sensor pad area TPA2 may correspond to the pads of the display panel 100 connected to the circuit board 300 shown in FIG. 7. The circuit board 300 may be disposed on the display pads DP, the first sensor pads TP1, and the second sensor pads TP2. The display pads DP, the first sensor pads TP1 and the second sensor pads TP2 may be electrically connected to the circuit board 300 using a low-resistance, high-reliability material such as an anisotropic conductive film or a SAP. Therefore, the display pads DP, the first sensor pads TP1 and the second sensor pads TP2 may be electrically connected to the touch driving circuit 400 disposed on the circuit board 300.

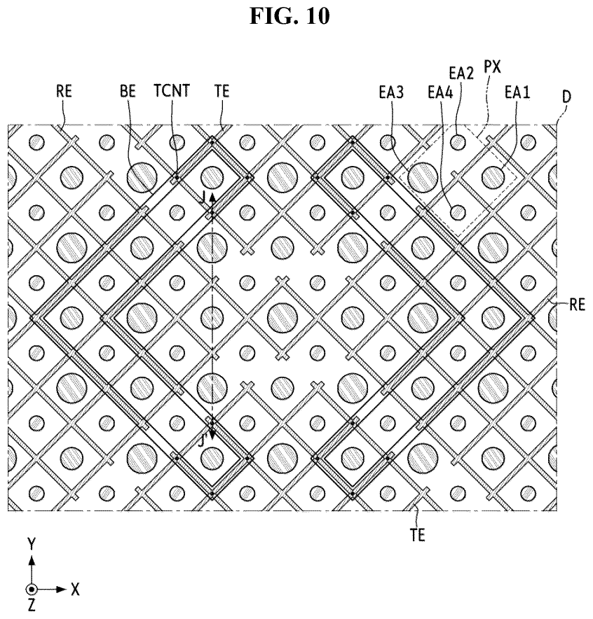

FIG. 10 is an enlarged view of area D shown in FIG. 9.

Referring to FIG. 10, the driving electrodes TE and the sensing electrodes RE are formed in the same layer and thus they may be spaced apart from each other. That is to say, there may be a gap between adjacent ones of the driving electrodes TE and the sensing electrodes RE.

In addition, the dummy patterns DE may also be disposed on the same layer as the driving electrodes TE and the sensing electrodes RE. That is to say, there may be a gap between adjacent ones of the driving electrodes TE and the dummy patterns DE and between adjacent ones of the sensing electrodes RE and the dummy patterns DE.

The bridge electrodes BE may be disposed on a different layer from the driving electrodes TE and the sensing electrodes RE. Each of the bridge electrodes BE may be bent at least once. Although the connection electrodes BE have the shape of angle brackets “<” or “>” in the example shown in FIG. 10, the shape of the connection electrodes BE when viewed from the top is not limited thereto. Since the driving electrodes TE adjacent to each other in the second direction (y-axis direction) are connected by the plurality of bridge electrodes BE, even if any of the bridge electrodes BE is disconnected, the driving electrodes TE can still be stably connected with each other in the second direction (y-axis direction). Although two adjacent ones of the driving electrodes TE are connected by two bridge electrodes BE in the example shown in FIG. 10, the number of bridge electrodes BE is not limited to two.

The bridge electrodes BE may overlap with the driving electrodes TE adjacent to one another in the second direction (y-axis direction) in the third direction (z-axis direction), which is the thickness direction of the substrate SUB. The bridge electrodes BE may overlap with the sensing electrodes RE in the third direction (z-axis direction). One side of each of the bridge electrodes BE may be connected to one of the driving electrodes TE adjacent to each other in the second direction (y-axis direction) through touch contact holes TCNT. The other side of each of the connection electrodes BEI may be connected to another one of the driving electrodes TE adjacent to each other in the second direction (y-axis direction) through touch contact holes TCNT.

The driving electrodes TE and the sensing electrodes RE may be electrically separated from each other at their intersections by virtue of the bridge electrodes BE. Accordingly, mutual capacitance can be formed between the driving electrodes TE and the sensing electrodes RE.

Each of the driving electrodes TE, the sensing electrodes RE and the bridge electrodes BE may have a mesh structure or a net structure when viewed from the top. In addition, each of the dummy patterns DE may have a shape of a mesh structure or a net structure when viewed from the top. Accordingly, the driving electrodes TE, the sensing electrodes RE, the bridge electrodes BE and the dummy patterns DE may be spaced apart from the light emitting areas EA1 to EA4 of each of the pixels. Therefore, it is possible to prevent the luminance of the lights output from the light emitting areas EA1 to EA4 from being lowered, which may occur as the lights are covered by the driving electrodes TE, the sensing electrodes RE, the bridge electrodes BE and the dummy patterns DE.

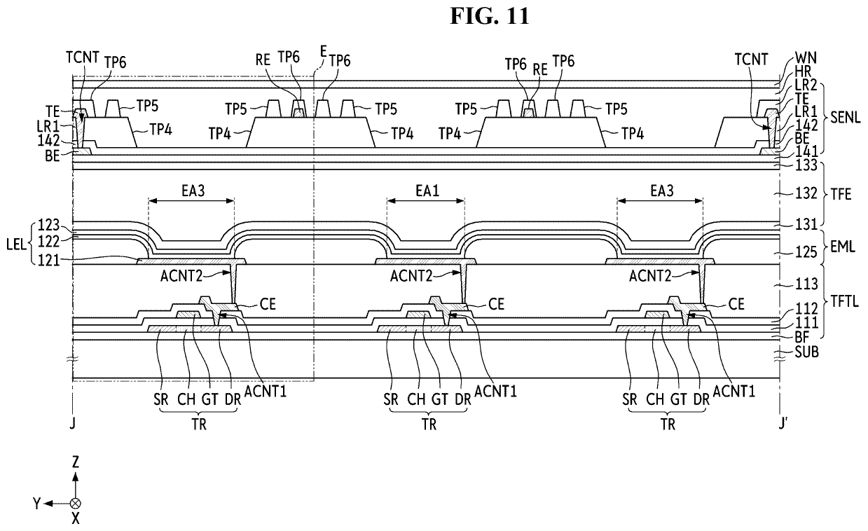

FIG. 11 is a cross-sectional view of the display panel, taken along line J-J′ of FIG. 10. The following description will focus on differences and the redundant description will be omitted.

Referring to FIG. 11, the display panel 101 may include the substrate SUB, the thin-film transistor layer TFTL disposed on the substrate SUB, the light emitting element layer EML, the encapsulation layer TFE, the touch sensing layer SENL, the high-refractive layer HR, and the window member WN.

The substrate SUB, the thin-film transistor layer TFTL, the light emitting element layer EML, the encapsulation layer TFE, and the window member WN may be formed in the same manner as described above with reference to FIG. 4.

The touch sensing layer SENL may be disposed on the encapsulation layer TFE. The touch sensing layer SENL may include a first touch insulating film 141, a touch bridge electrode BE, a second touch insulating film 142, a driving electrode TE, a sensing electrode RE, a first low-refractive layer LR1, and a second low-refractive layer LR2.

The first touch insulating film 141 may be disposed on the encapsulation layer TFE. The first touch insulating film 141 may be, but is not limited to, a silicon nitride layer, a silicon oxynitride layer, a silicon oxide layer, a titanium oxide layer, or an aluminum oxide layer.

The touch bridge electrode BE may be disposed on the first touch insulating film 141. The touch connection electrode BE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second touch insulating film 142 may be disposed on the touch bridge electrode BE and the first touch insulating film 141. The second touch insulating film 142 may be formed of an inorganic layer, for example, a silicon nitride layer, a silicon oxynitride layer, a silicon oxide layer, a titanium oxide layer, or an aluminum oxide layer.

The first low-refractive layer LR1 may be disposed on the second touch insulating film 142. The first low-refractive layer LR1 may include a first organic pattern TP4. The first low-refractive layer LR may include an organic material. The refractive index of the first low-refractive layer LR1 may be lower than the refractive index of the high-refractive layer HR.

The first low-refractive layer LR1 may include a first organic pattern TP4. The first organic pattern TP1 may be disposed on the second touch insulating film 142. The first organic pattern TP4 may overlap with the pixel-defining layer 125 in the third direction (z-axis direction). The first organic pattern TP4 may not overlap with the first to fourth light emitting areas EA1 to EA4 in the third direction (z-axis direction).

The driving electrodes TE and the sensing electrodes RE may be disposed on the first low-refractive layer LR1. In addition to the driving electrodes TE and the sensing electrodes RE, the dummy patterns DE, the first driving lines TL1, the second driving lines TL2 and the sensing lines RL shown in FIG. 9 may be disposed on the first low-refractive layer LR1.

The driving electrodes TE and the sensing electrodes RE may overlap with the touch connection electrode BE in the third direction (z-axis direction). The driving electrode TE may be connected to the touch bridge electrode BE through a touch contact hole TCNT penetrating the second touch insulating film 142 and the first low-refractive layer LR1.

The second low-refractive layer LR2 may be disposed on the first low-refractive layer LR1, the driving electrodes TE, the sensing electrodes RE. The second low-refractive layer LR2 may include an organic material. The refractive index of the second low-refractive layer LR2 may be lower than the refractive index of the high-refractive layer HR. The refractive index of the second low-refractive layer LR2 may be substantially equal to the refractive index of the first low-refractive layer LR1. The second low-refractive layer LR2 may include the same material as the first low-refractive layer LR1. The second low-refractive layer LR2 may be formed integrally with the first low-refractive layer LR1.

The second low-refractive layer LR2 may include second organic patterns TP5 and third organic patterns TP6. The second organic patterns TP5 may be arranged on the first organic pattern TP4. The third organic patterns TP6 may be disposed on the first organic pattern TP4, the driving electrode TE, and the sensing electrode RE. The second organic patterns TP5 and the third organic patterns TP6 may be spaced apart from each other. Although the height of the second organic patterns TP5 is equal to the height of the third organic patterns TP6 in the drawings, the embodiments of the present disclosure are not limited thereto.

Among the light emitting areas EA1 to EA4, the second organic pattern TP5 adjacent to one of the light emitting areas may be disposed closer to the one of the light emitting areas than the third organic pattern TP5 adjacent to the one of the light emitting areas. For example, the second organic pattern TP5 adjacent to the first light emitting area EA3 may be disposed closer to the first light emitting area EA1 than the third organic pattern TP6 adjacent to the first light emitting area EA1. The second organic pattern TP5 and the third organic pattern TP6 may be arranged in the same manner also in the second to fourth light emitting areas EA2 to EA4.

The third organic patterns TP6 may cover the driving electrodes TE or the sensing electrodes RE. The third organic patterns TP6 may be organic insulating films for the driving electrodes TE or the sensing electrodes RE.

The high-refractive layer HR may be disposed over the second low-refractive layer LR2, the first low-refractive layer LR1, and the second touch insulating film 142. The high-refractive layer HR may provide a flat surface over the first low-refractive layer LR1 and the second low-refractive layer LR2.

The refractive index of the high-refractive layer HR may be higher than the refractive index of the first low-refractive layer LR1 and the refractive index of the second low-refractive layer LR2. Accordingly, light passing through the interface between the high-refractive layer HR and the first low-refractive layer LR1 or the interface between the high-refractive layer HR and the second low-refractive layer LR2 may be refracted.

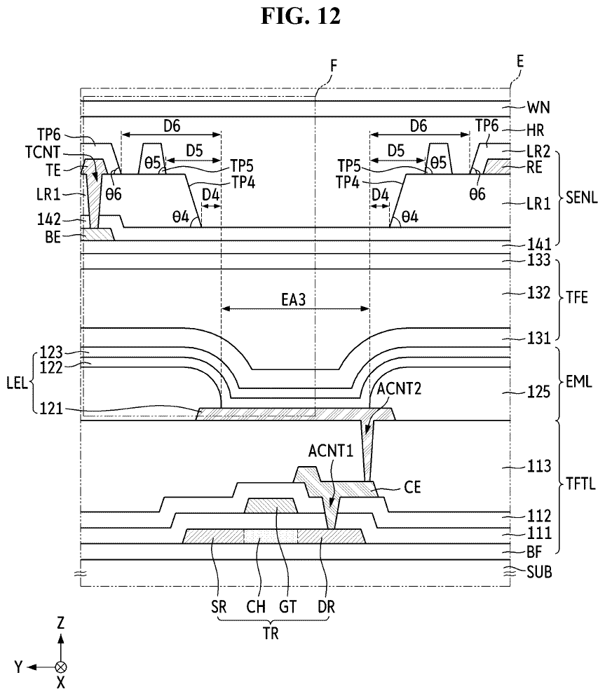

FIG. 12 is an enlarged view of area E shown in FIG. 11.

Referring to FIG. 12, the first organic pattern TP4 may be spaced apart from the third light emitting area EA3 in the first direction (x-axis direction). For example, the distance D4 between the side surface of the first organic pattern TP4 adjacent to the third light emitting area EA3 and the third light emitting area EA3 in the first direction (x-axis direction) may be equal to or greater than 0.1 μm.

The angle θ4 formed by the side surface of the first organic pattern TP1 adjacent to the third light emitting area EA3 and the lower surface of the first organic pattern TP4 may be smaller than the critical angle. The critical angle may be an angle at which light output from the third light emitting area EA3 is totally reflected at the interface between the first organic pattern TP4 and the high-refractive layer HR (fourth organic pattern).

The second organic pattern TP5 may be spaced apart from the third light emitting area EA3 in the first direction (x-axis direction). The side surface of the second organic pattern TP2 adjacent to the third light emitting area EA3 in the first direction (x-axis direction) may be spaced apart from the side surface of the first organic pattern TP4 adjacent to the third light emitting area EA3. The distance D5 between the side surface of the second organic pattern TP5 adjacent to the third light emitting area EA3 and the third light emitting area EA3 may be greater than the distance D4 between the side surface of the first organic pattern TP4 adjacent to the third light emitting area EA3 and the third light emitting area EA3 in the first direction (x-axis direction).

The angle θ5 formed by the side surface of the second organic pattern TP5 adjacent to the third light emitting area EA3 and the lower surface of the second organic pattern TP5 may be greater than the angle θ4 formed by the side surface of the first organic pattern TP4 adjacent to the third light emitting area EA3 and the lower surface of the first organic pattern TP4. The angle θ5 formed by the side surface of the second organic pattern TP5 adjacent to the third light emitting area EA3 and the lower surface of the second organic pattern TP5 may be greater than the critical angle.

The third organic pattern TP6 may be spaced apart from the third light emitting area EA3 in the first direction (x-axis direction). The side surface of the third organic pattern TP3 may be spaced apart from the side surface of the first organic pattern TP4 in the first direction (x-axis direction). The side surface of the third organic pattern TP6 may be spaced apart from the side surface of the second organic pattern TP5 in the first direction (x-axis direction). The distance D6 between the side surface of the third organic pattern TP6 adjacent to the third light emitting area EA3 and the third light emitting area EA3 may be greater than the distance D5 between the side surface of the second organic pattern TP5 adjacent to the third light emitting area EA3 and the third light emitting area EA3 in the first direction (x-axis direction).

The angle θ6 formed by the side surface of the third organic pattern TP6 adjacent to the third light emitting area EA3 and the lower surface of the third organic pattern TP6 may be greater than the angle θ5 formed by the side surface of the second organic pattern TP5 adjacent to the third light emitting area EA3 and the lower surface of the second organic pattern TP5. The angle θ6 formed by the side surface of the third organic pattern TP6 adjacent to the third light emitting area EA3 and the lower surface of the third organic pattern TP6 may be greater than the critical angle. The angle θ6 formed by the side surface of the third organic pattern TP6 adjacent to the third light emitting area EA3 and the lower surface of the third organic pattern TP6 may be substantially equal to the angle θ5 formed by the side surface of the second organic pattern TP5 adjacent to the third light emitting area EA3 and the lower surface of the second organic pattern TP5.

A slit SLT may be formed between the second organic patterns TP5 and the third organic patterns TP6. In the slit SLT, the upper surface of the first organic pattern TP4 may be exposed.

One edge of a slit SLT may correspond to one side surface of a second organic pattern TP5, and the other edge of the slit SLT may correspond to one side surface of a third organic pattern TP6. The side surface of the second organic pattern TP5 may be the opposite side surface of the other side surface of the second organic pattern TP5 adjacent to the second light emitting area EA2. The side surface of the third organic pattern TP6 may be the side surface closer to the second light emitting area EA2.

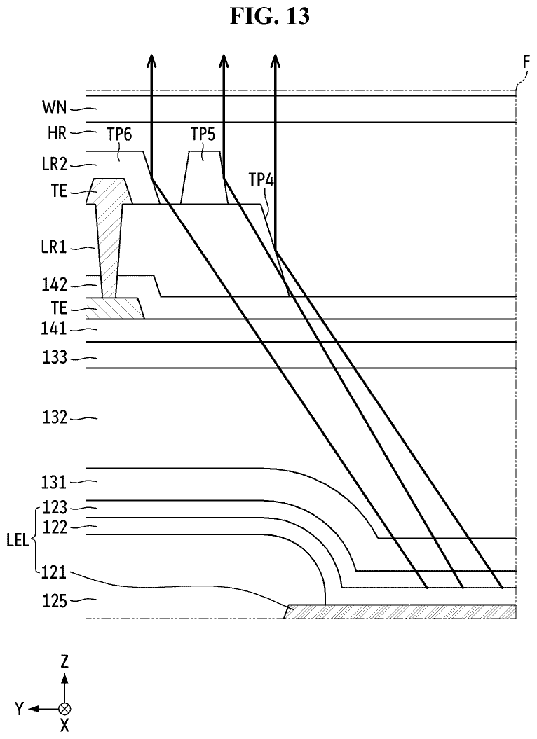

In FIG. 12, the first to third organic patterns TP1 to TP3 adjacent to the third light emitting area EA3 have been described as an example. The first to third organic patterns TP1 to TP3 adjacent to the first light emitting area EA1, the second light emitting area EA2 and the fourth light emitting area EA4 may also be formed in the same manner as described above. FIG. 13 is an enlarged view of area F shown in FIG. 12.

Referring to FIG. 13, a portion of the light emitted from the light emitting layer 122 may be incident on a side surface of the first organic pattern TP4. The incidence angle of the light incident on the side surface of the first organic pattern TP4 may be smaller than the critical angle. Since the refractive index of the high-refractive layer HR (fourth organic pattern) is greater than the refractive index of the first organic pattern TP4, light emitted from the light emitting layer 122 may be refracted at the side surface of the first organic pattern TP1 and may exit to the outside of the display device 10.

A portion of the light emitted from the light emitting layer 122 may be incident on the side surfaces of the second organic pattern TP5. The incidence angle of the light incident on the side surface of the second organic pattern TP5 may be greater than the critical angle. Since the refractive index of the high-refractive layer HR (fourth organic pattern) is greater than the refractive index of the second organic patterns TP5, light emitted from the light emitting layer 122 may be totally reflected at the side surface of the second organic pattern TP5 and may exit to the outside of the display device 10.

A portion of the light emitted from the light emitting layer 122 may be incident on the side surfaces of the third organic pattern TP6. The incidence angle of the light incident on the side surface of the third organic pattern TP6 may be greater than the critical angle. Since the refractive index of the high-refractive layer HR (fourth organic pattern) is greater than the refractive index of the third organic patterns TP6, light emitted from the light emitting layer 122 may be totally reflected at the side surface of the third organic pattern TP6 and may exit to the outside of the display device 10.

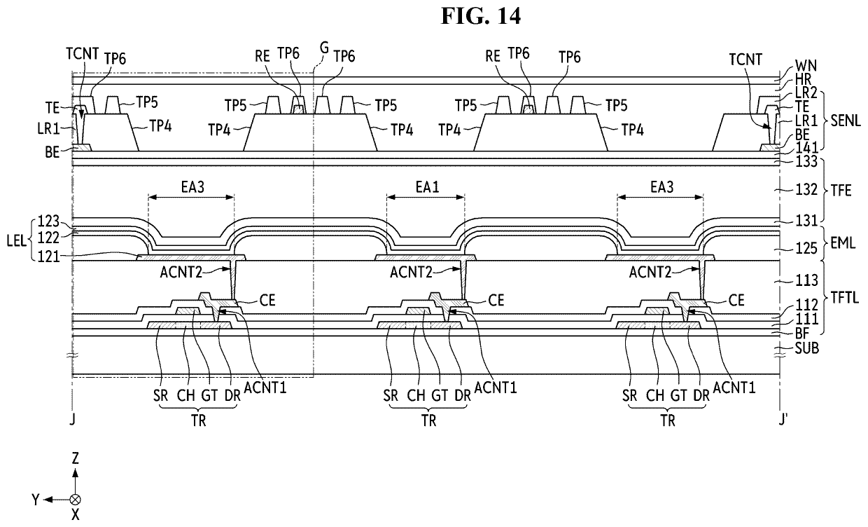

FIG. 14 is a cross-sectional view of the display panel, taken along line J-J′ of FIG. 10 according to another embodiment. The following description will focus on differences and the redundant description will be omitted.

Referring to FIG. 14, the display panel 101 may include the substrate SUB, the thin-film transistor layer TFTL disposed on the substrate SUB, the light emitting element layer EML, the encapsulation layer TFE, the touch sensing layer SENL, the high-refractive layer HR, and the window member WN.

The substrate SUB, the thin-film transistor layer TFTL, the light emitting element layer EML, the encapsulation layer TFE, and the window member WN may be formed in the same manner as described above with reference to FIG. 4.

The high-refractive layer HR may be formed in the same manner as described above in FIG. 11.

The touch sensing layer SENL may be disposed on the encapsulation layer TFE. The touch sensing layer SENL may include a first touch insulating film 141, a touch bridge electrode BE, a driving electrode TE, a sensing electrode RE, a first low-refractive layer LR1, and a second low-refractive layer LR2.

The first touch insulating film 141 may be disposed on the encapsulation layer TFE.

The touch bridge electrode BE may be disposed on the first touch insulating film 141.

The first low-refractive layer LR1 may be disposed on the touch bridge electrode BE and the first touch insulating film 141. The first low-refractive layer LR1 may include a first organic pattern TP4. The first organic pattern TP4 may be disposed on the touch bridge electrode BE and the first touch insulating film 141.

The driving electrodes TE and the sensing electrodes RE may be disposed on the first low-refractive layer LR1. The driving electrodes TE and the sensing electrodes RE may overlap with the touch connection electrode BE in the third direction (z-axis direction). The driving electrode TE may be connected to the touch bridge electrode BE through a touch contact hole TCNT penetrating the first low-refractive layer LR1.

The second low-refractive layer LR2 may be disposed on the first low-refractive layer LR1, the driving electrodes TE, the sensing electrodes RE. The second low-refractive layer LR2 may be formed integrally with the first low-refractive layer LR1.

The second low-refractive layer LR2 may include second organic patterns TP5 and third organic patterns TP6. The second organic patterns TP5 may be arranged on the first organic pattern TP4. The third organic patterns TP6 may be disposed on the first organic pattern TP4, the driving electrode TE, and the sensing electrode RE. The second organic patterns TP5 and the third organic patterns TP6 may be spaced apart from each other. Although the height of the second organic patterns TP5 is equal to the height of the third organic patterns TP6 in the drawings, the embodiments of the present disclosure are not limited thereto.

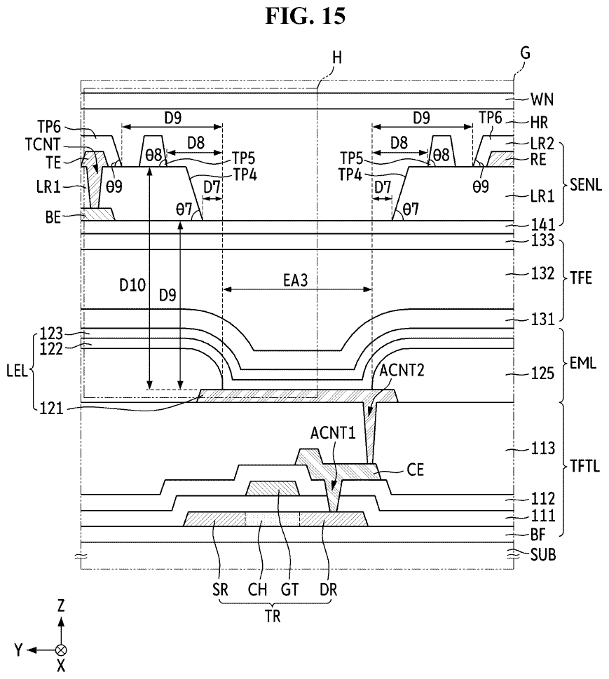

FIG. 15 is an enlarged view of area G shown in FIG. 14. The following description will focus on differences and the redundant description will be omitted.

Referring to FIG. 15, the first organic pattern TP4 may be spaced apart from the third light emitting area EA3 in the first direction (x-axis direction). For example, the distance D7 between the side surface of the first organic pattern TP4 adjacent to the third light emitting area EA3 and the third light emitting area EA3 in the first direction (x-axis direction) may be equal to or greater than 0.1 μm.

The angle θ7 formed by the side surface of the first organic pattern TP1 adjacent to the third light emitting area EA3 and the lower surface of the first organic pattern TP4 may be smaller than the critical angle. The critical angle may be an angle at which light output from the third light emitting area EA3 is totally reflected at the interface between the first organic pattern TP4 and the high-refractive layer HR (fourth organic pattern).

The second organic patterns TP5 may be spaced apart from the third light emitting area EA3 in the first direction (x-axis direction). The side surface of the second organic pattern TP2 adjacent to the third light emitting area EA3 in the first direction (x-axis direction) may be spaced apart from the side surface of the first organic pattern TP4 adjacent to the third light emitting area EA3. The distance D8 between the side surface of the second organic pattern TP5 adjacent to the third light emitting area EA3 and the third light emitting area EA3 may be greater than the distance D7 between the side surface of the first organic pattern TP4 adjacent to the third light emitting area EA3 and the third light emitting area EA3 in the first direction (x-axis direction).

The angle θ8 formed by the side surface of the second organic pattern TP5 adjacent to the third light emitting area EA3 and the lower surface of the second organic pattern TP5 may be greater than the angle θ7 formed by the side surface of the first organic pattern TP4 adjacent to the third light emitting area EA3 and the lower surface of the first organic pattern TP4. The angle θ8 formed by the side surface of the second organic pattern TP5 adjacent to the third light emitting area EA3 and the lower surface of the second organic pattern TP5 may be greater than the critical angle.

The third organic patterns TP6 may be spaced apart from the third light emitting area EA3 in the first direction (x-axis direction). The side surface of the third organic pattern TP3 may be spaced apart from the side surface of the first organic pattern TP4 in the first direction (x-axis direction). The side surface of the third organic pattern TP6 may be spaced apart from the side surface of the second organic pattern TP5 in the first direction (x-axis direction). The distance D9 between the side surface of the third organic pattern TP6 adjacent to the third light emitting area EA3 and the third light emitting area EA3 may be greater than the distance D8 between the side surface of the second organic pattern TP5 adjacent to the third light emitting area EA3 and the third light emitting area EA3 in the first direction (x-axis direction).

The angle θ9 formed by the side surface of the third organic pattern TP6 adjacent to the third light emitting area EA3 and the lower surface of the third organic pattern TP6 may be greater than the angle θ8 formed by the side surface of the second organic pattern TP5 adjacent to the third light emitting area EA3 and the lower surface of the second organic pattern TP5. The angle θ9 formed by the side surface of the third organic pattern TP6 adjacent to the third light emitting area EA3 and the lower surface of the third organic pattern TP6 may be greater than the critical angle. The angle θ9 formed by the side surface of the third organic pattern TP6 adjacent to the third light emitting area EA3 and the lower surface of the third organic pattern TP6 may be substantially equal to the angle θ8 formed by the side surface of the second organic pattern TP5 adjacent to the third light emitting area EA3 and the lower surface of the second organic pattern TP5.

Compared to FIG. 12, since the second touch insulating film 142 is eliminated in the example shown in FIG. 15, the distance D10 between the first low-refractive layer LR1 and the light emitting layer 122 and the distance D11 between the second low-refractive layer LR2 and the light emitting layer 122 in the third direction (z-axis direction) may be shortened. Accordingly, the distance D7 between the side surface of the first organic pattern TP4 adjacent to the third light emitting area EA3 and the third light emitting area EA3, the distance D8 between the side surface of the second organic pattern TP5 adjacent to the third light emitting area EA3 and the third light emitting area EA3, and the distance D9 between the side surface of the third organic pattern TP6 adjacent to the third light emitting area EA3 and the third light emitting area EA3 in the first direction (x-axis direction) may be reduced compared to the example shown in FIG. 12.

This is because light is emitted from the light emitting layer 122 toward the front side, and the light that is emitted from the light emitting layer 122 and is directed to the first low-refractive layer LR1 or the second low-refractive layer LR2 travels in a diagonal direction intersecting the first direction (x-axis direction) and the third direction (z-axis direction). If the distance D7 between the first low-refractive layer LR1 and the light emitting area or the distance D8 or D9 between the second low-refractive layer LR2 and the light emitting area in the first direction (x-axis direction) is greater than a predetermined distance, light emitted from the light emitting layer 122 may not reach the first low-refractive layer LR1. The predetermined distance may be proportional to the distance D10 between the first low-refractive layer LR1 and the light emitting area or the distance D11 between the second low-refractive layer LR and the light emitting area in the third direction (z-axis direction).

In FIG. 15, the first to third organic patterns TP1 to TP3 adjacent to the third light emitting area EA3 have been described as an example. The first to third organic patterns TP1 to TP3 adjacent to the first light emitting area EA1, the second light emitting area EA2 and the fourth light emitting area EA4 may also be formed in the same manner as described above.

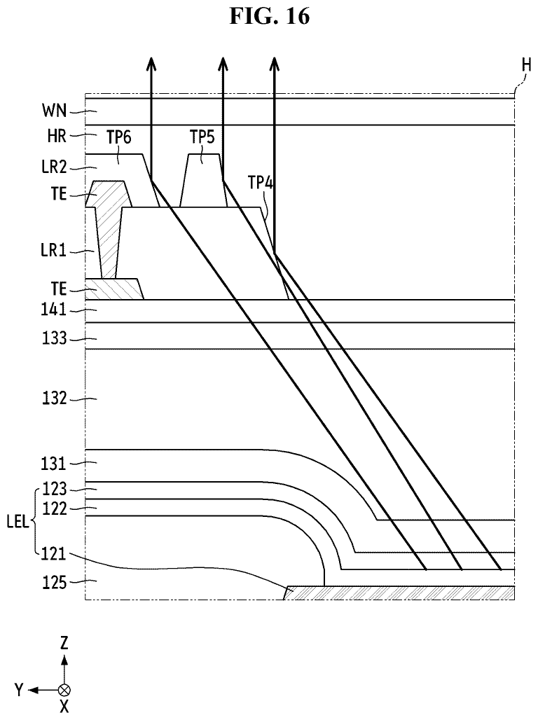

FIG. 16 is an enlarged view of area H shown in FIG. 15.

Referring to FIG. 16, a portion of the light emitted from the light emitting layer 122 may be incident on a side surface of the first organic pattern TP4. The incidence angle of the light incident on the side surface of the first organic pattern TP4 may be smaller than the critical angle. Since the refractive index of the high-refractive layer HR (fourth organic pattern) is greater than the refractive index of the first organic pattern TP4, light emitted from the light emitting layer 122 may be refracted at the side surface of the first organic pattern TP1 and may exit to the outside of the display device 10.

A portion of the light emitted from the light emitting layer 122 may be incident on the side surfaces of the second organic patterns TP5. The incidence angle of the light incident on the side surface of the second organic patterns TP5 may be greater than the critical angle. Since the refractive index of the high-refractive layer HR (fourth organic pattern) is greater than the refractive index of the second organic patterns TP5, light emitted from the light emitting layer 122 may be totally reflected at the side surface of the second organic patterns TP5 and may exit to the outside of the display device 10.

A portion of the light emitted from the light emitting layer 122 may be incident on the side surfaces of the third organic patterns TP6. The incidence angle of the light incident on the side surfaces of the third organic patterns TP6 may be greater than the critical angle. Since the refractive index of the high-refractive layer HR (fourth organic pattern) is greater than the refractive index of the third organic patterns TP6, light emitted from the light emitting layer 122 may be totally reflected at the side surface of the third organic patterns TP6 and may exit to the outside of the display device 10.

Although the embodiments of the present disclosure have been described with reference to the accompanying drawings, those of ordinary skill in the art to which the present disclosure pertains will understand that the present disclosure may be embodied in other specific forms without changing the technical spirit or essential features thereof. Therefore, it should be understood that the embodiments described above are illustrative in all aspects and not restrictive.

What is claimed is:

1. A display device comprising:
a substrate;
a plurality of light-emitting elements disposed on the substrate, the light-emitting elements being arranged in a plurality of light emitting areas, which output light, respectively;
an encapsulation layer disposed on the plurality of light-emitting elements;
a first organic pattern disposed on the encapsulation layer and located between adjacent ones of the light emitting areas;
a second organic pattern and a third organic pattern, which are disposed on the first organic pattern, spaced apart from each other, and between the adjacent ones of the light emitting areas; and
a fourth organic pattern disposed on the first organic pattern, the second organic pattern and the third organic pattern,
wherein a refractive index of the first organic pattern, a refractive index of the second organic pattern and a refractive index of the third organic pattern are each smaller than a refractive index of the fourth organic pattern.

2. The display device of claim 1, wherein the refractive index of the first organic pattern, the refractive index of the second organic pattern and the refractive index of the third organic pattern are equal to one another.

3. The display device of claim 2, wherein the first organic pattern, the second organic pattern and the third organic pattern comprise a same material.

4. The display device of claim 1, wherein the first organic pattern, the second organic pattern and the third organic pattern are formed integrally.

5. The display device of claim 4, wherein an upper surface of the first organic pattern is exposed between the second organic pattern and the third organic pattern.

6. The display device of claim 1, wherein an angle formed by a side surface of the first organic pattern and a lower surface of the first organic pattern is smaller than an angle formed by a side surface of the second organic pattern and a lower surface of the second organic pattern.

7. The display device of claim 6, wherein the angle formed by the side surface of the first organic pattern and the lower surface of the first organic pattern is smaller than a first angle, and
wherein the first angle is a critical angle at which total reflection of light occurs between the first organic pattern and the fourth organic pattern.

8. The display device of claim 7, wherein the angle formed by the side surface of the second organic pattern and the lower surface of the second organic pattern is greater than the first angle.

9. The display device of claim 8, wherein an angle formed by a side surface of the third organic pattern and a lower surface of the third organic pattern is equal to the angle formed by the side surface of the second organic pattern and the lower surface of the second organic pattern.

10. The display device of claim 1, wherein a minimum distance between one of the light emitting areas and the first organic pattern is shorter than a minimum distance between the one of the light emitting areas and the second organic pattern in a direction perpendicular to a thickness direction of the substrate.

11. A display device comprising:
a substrate;
a plurality of light-emitting elements disposed on the substrate, the light-emitting elements being arranged in a plurality of light emitting areas, which output light, respectively;
an encapsulation layer disposed on the plurality of light-emitting elements;
a first organic pattern disposed on the encapsulation layer and located between adjacent ones of the light emitting areas;
a second organic pattern and a third organic pattern, which are disposed on the first organic pattern, spaced apart from each other, and between the adjacent ones of the light emitting areas; and
a touch electrode disposed on the first organic pattern,
wherein the third organic pattern covers the touch electrode.

12. The display device of claim 11, further comprising:
a first inorganic insulating film disposed between the encapsulation layer and the first organic pattern; and
a connecting electrode disposed on the first inorganic insulating film.

13. The display device of claim 12, wherein the touch electrode is connected to the connecting electrode through a touch contact hole penetrating the first organic pattern.

14. The display device of claim 12, further comprising:
a second inorganic insulating film disposed on the connecting electrode and the first inorganic insulating film.

15. The display device of claim 14, wherein the touch electrode is connected to the connecting electrode through a touch contact hole penetrating the first organic pattern and the second inorganic insulating film.

16. The display device of claim 11, further comprising:
a fourth organic pattern disposed on the first organic pattern, the second organic pattern and the third organic pattern,
wherein a refractive index of the first organic pattern, a refractive index of the second organic pattern, and a refractive index of the third organic pattern are each lower than a refractive index of the fourth organic pattern.

17. The display device of claim 16, wherein an angle formed by a side surface of the first organic pattern and a lower surface of the first organic pattern is smaller than an angle formed by a side surface of the second organic pattern and a lower surface of the second organic pattern.

18. The display device of claim 17, wherein the angle formed by the side surface of the first organic pattern and the lower surface of the first organic pattern is smaller than a first angle, and
wherein the first angle is a critical angle at which total reflection of light occurs between the first organic pattern and the fourth organic pattern.

19. The display device of claim 18, wherein the angle formed by the side surface of the second organic pattern and the lower surface of the second organic pattern is greater than the first angle.

20. An electronic device including a display device, the display device comprising:
a substrate;
a plurality of light-emitting elements disposed on the substrate, the light-emitting elements being arranged in a plurality of light emitting areas, which output light, respectively;
an encapsulation layer disposed on the plurality of light-emitting elements;
a first organic pattern disposed on the encapsulation layer and located between adjacent ones of the light emitting areas;
a second organic pattern and a third organic pattern, which are disposed on the first organic pattern, spaced apart from each other, and between the adjacent ones of the light emitting areas; and
a fourth organic pattern disposed on the first organic pattern, the second organic pattern and the third organic pattern,
wherein a refractive index of the first organic pattern, a refractive index of the second organic pattern and a refractive index of the third organic pattern are each smaller than a refractive index of the fourth organic pattern.
